(19) United States
(12) Patent Application Publication
(10) Pub. No.: US 2018/0172754 A1
(43) Pub. Date: Jun. 21, 2018

(54) ROTATING DIODE FAULT DETECTION

(71) Applicant: GE Aviation Systems LLC, Grand Rapids, MI (US)

(72) Inventor: David Andrew Woodburn, Beavercreek, OH (US)

(21) Appl. No.: 15/809,192

(22) Filed: Nov. 10, 2017

Related U.S. Application Data
(60) Provisional application No. 62/435,285, filed on Dec. 16, 2016.

(51) Int. Cl. G01R 31/26; G01R 31/00; G01R 31/34

(52) U.S. Cl. CPC G01R 31/2632; G01R 31/34; G01R 31/008

(57) ABSTRACT

Systems and methods for detecting a diode fault are provided. In one example implementation, a method for determining a diode fault condition in a rotating rectifier associated with an electrical machine in an aircraft includes obtaining, by one or more processors, a signal associated with a diode of a rotating rectifier; determining, by the one or more processors, a frequency of interest; isolating, by the one or more processors, the frequency of interest from the signal to generate an isolated signal; determining, by the one or more processors, an amplitude of the isolated frequency of interest; and determining, by the one or more processors, a diode fault condition based on the determined amplitude.

### PRIORITY CLAIM

The present application claims the benefit of priority of U.S. Provisional Patent Application No. 62/435,285, entitled “ROTATING DIODE FAULT DETECTION,” filed Dec. 22, 2016, which is incorporated herein by reference for all purposes.

### FIELD

The present subject matter relates generally to detecting fault conditions associated with a diode in a rotating rectifier included as part of an electrical power system of an aircraft or other aerial vehicle.

### BACKGROUND

An aircraft can include a variety of components. Aircraft can include electrical power systems for the generation of electrical power for various loads included as part of the aircraft. Some electrical power systems can include electrical machines, such as electric motors and/or electric generators, for the generation of electricity. In the aircraft industry, it is common to find combination motor-generators, where a motor is used to power a generator, and, depending on the configuration, the motor also functions as a generator. Regardless of the configuration, generators typically include a rotor having main windings that are driven to rotate by a source of rotation, such as an electrical or mechanical machine, which for some aircraft may be a gas turbine engine. In some applications, the generators initially generate alternating current (AC), which is rectified to generate direct current (DC) for DC components on the aircraft.

Some electrical machines include two stages: an exciter and a main. Each stage extracts more power from the mechanical rotation of the machine. In order to run, the exciter requires a field current on its stator to produce more current on its rotor. Likewise, the main requires a field current on its rotor to produce more current on its stator. The current from the exciter supplies the current into the main. Because the current from the rotor of the exciter is AC, but the field current into the rotor of the main must be DC, a rectifier is needed to convert the AC current into DC current. However, because this rectifier is on the rotating part of the electrical machine, it is generally very difficult to monitor what is happening with its diodes. So, there is a need to detect fault conditions associated with one or more diodes of the rotating rectifier.

### BRIEF DESCRIPTION

Aspects and advantages of embodiments of the present disclosure will be set forth in part in the following description, or may be learned from the description, or may be learned through practice of the embodiments.

One example aspect of the present disclosure is directed to a method for determining a diode fault condition in a rotating rectifier associated with an electrical machine in an aircraft. The method includes obtaining, by one or more processors, a signal associated with a diode of a rotating rectifier; determining, by the one or more processors, a frequency of interest; isolating, by the one or more processors, the frequency of interest from the signal to generate an isolated signal; determining, by the one or more processors, an amplitude of the isolated frequency of interest; and determining, by the one or more processors, a diode fault condition based on the determined amplitude.

Another example aspect of the present disclosure is directed to a system for determining a diode fault condition in a rotating rectifier associated with an electrical machine in an aircraft. The system can include one or more memory devices and one or more processors. The one or more processors can be configured to obtain a signal associated with a diode of the rotating rectifier. The one or more processors can be further configured to obtain a frequency of interest and isolate the frequency of interest from the signal to generate an isolated signal. The one or more processors can be further configured to determine an amplitude of the isolated frequency of interest. The one or more processors can be further configured to determine a diode fault condition based on the determined amplitude.

Yet another example aspect of the present disclosure is directed to an aerial vehicle comprising an electrical machine and a rotating rectifier. The rotating rectifier can be associated with the electrical machine. The aerial vehicle can include the system for determining a diode fault condition in a rotating rectifier associated with the electrical machine.

Other example aspects of the present disclosure are directed to systems, methods, aircrafts, devices, non-transitory computer-readable media for detecting a diode fault. Variations and modifications can be made to these example aspects of the present disclosure.

These and other features, aspects, and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example aircraft in accordance with example embodiments of the present disclosure;

FIG. 2 depicts a cross-sectional view of an electrical machine according to example embodiments of the present disclosure;

FIG. 3 depicts a rectifier assembly according to example embodiments of the present disclosure;

FIG. 4 depicts an exploded view of a rectifier assembly according to example embodiments of the present disclosure;

FIG. 5 depicts a flow diagram of an example method according to example embodiments of the present disclosure; and

FIG. 6 depicts a computing system for implementing one or more aspects according to example embodiments of the present disclosure.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

As used in the specification and the appended claims, the singular forms “a,” “an,” and “the” include plural referents unless the context clearly dictates otherwise. The use of the term “about” in conjunction with a numerical value refers to within 25% of the stated amount.

Example aspects of the present disclosure are directed to determining a diode fault condition associated with a diode included as part of a rotating rectifier used in an electrical power system associated with an aircraft. When a diode fault condition occurs, the faulted diode can create a noticeable ripple at a frequency proportional to a speed of an associated rotating shaft. For example, if one diode out of three diodes in a rotating rectifier associated with a synchronous generator has failed, a ripple whose frequency is a product of a shaft speed and a number of pole pairs of an exciter of the generator can appear on an excitation field current. The frequency can be called a frequency of interest.

Any number of methods can be used to monitor and/or isolate the signals at the frequency of interest. For example, a band-pass filter targeting the frequency of interest, a pseudo-Park transform with a reference frequency equal to the frequency of interest, a phase-locked loop locked to the frequency of interest, a Fourier-series integration at just the frequency of interest. Full fast Fourier transform (FFT) analysis may not be required to isolate the frequency of interest.

An amplitude of the frequency of interest can be determined. When the amplitude exceeds a first (higher) threshold, a shorted diode can be determined to be the fault condition. When the amplitude exceeds a second (lower) threshold for a given amount of time without exceeding the first threshold, an open diode can be determined to be the fault condition. The designation of “first” and “second” to the thresholds does not indicate an order in which the thresholds were exceeded. As detailed above, the second threshold can be exceeded before the first threshold is exceeded. A signal indicative of the determined fault condition can be transmitted to a user or device (e.g., aircraft professional, technician, controller, etc.).

The systems and methods described herein may provide a number of technical effects and benefits. For instance, by detecting a diode fault using a frequency of interest, the diode fault can be detected without the need for additional sensors other than those typically present in aircraft electrical power systems. As a result, the methods and systems can allow for the detection of diode fault conditions without adding more complex, expensive hardware. For example, the systems and methods can detect a frequency of interest within a signal, isolate the detected frequency of interest from the signal, determine an amplitude of the isolated frequency of interest, determine a diode fault condition based on the determined amplitude, and transmit a signal indicative of the determined diode fault condition. This can allow the aircraft diagnostic computing systems to conserve resources in the event of a diode fault, for instance, by not requiring full FFT to identify the diode fault condition. Thus, the aircraft can save computational resources that may otherwise be used for the coordination of other vehicle maintenance measures. Accordingly, the saved processing and storage resources of the aircraft can be consumed for more critical, core functions of the aircraft.

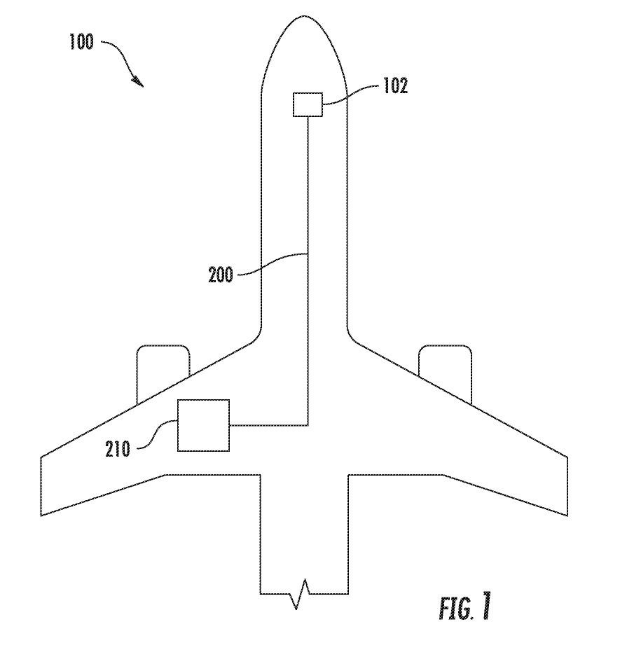

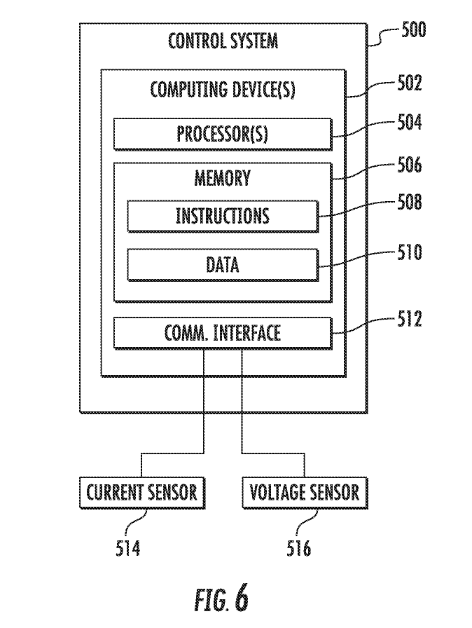

FIG. 1 depicts an example aircraft 100 in accordance with example embodiments of the present disclosure. The aircraft 100 can include a control system 102, such as the control system 600 described in FIG. 6. The aircraft 100 can include an electrical power system 200. The electrical power system 200 can be used to power one or more loads on the aircraft 100.

In some embodiments, the electrical power system 200 can include one or more electrical machines 210 that can be used to generate power. The electrical machine(s) 210 can include a rotating rectifier. The rotating rectifier can include a plurality of diodes. Example aspects of the present disclosure are directed to detecting fault conditions associated with the plurality of diodes in the rotating rectifier.

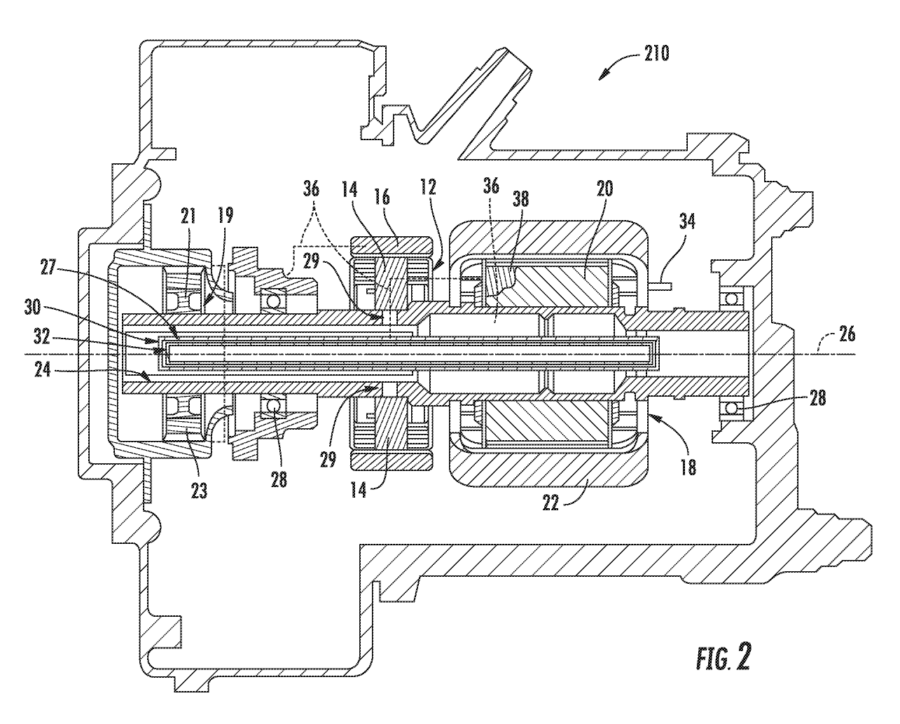

One example electrical machine assembly 210 with a rotating rectifier is illustrated in FIGS. 2-4 for example purposes. Those of ordinary skill in the art, using the disclosures provided herein, will understand that example aspects of the present disclosure can be used with any suitable electrical machine and rotating rectifier assembly without deviating from the scope of the present disclosure.

FIG. 2 schematically illustrates an electrical machine assembly 210 comprising a first machine 12 (e.g., an exciter) having an exciter rotor 14 and an exciter stator 16, and a second machine 18 (e.g., a main machine) having a main machine rotor 20 and a main machine stator 22. The electrical machine assembly 210 is further shown comprising a permanent magnet generator (PMG) 19 having a PMG rotor 21 and a PMG stator 23. At least one power connection is provided on the exterior of the electrical machine assembly 210 to provide for the transfer of electrical power to and from the electrical machine assembly 210. Power is transmitted by this power connection, shown as an electrical power cable 34, to the electrical load and may provide for a three-phase output with a ground reference from the electrical machine assembly 210.

The electrical machine assembly 210 further comprises a thermally conductive rotatable shaft 24 mechanically coupled to a source of axial rotation, which may be a gas turbine engine (not shown), about a common axis 26. The rotatable shaft 24 is supported by spaced bearings 28 and includes access openings 29 radially spaced about the shaft 24. The exciter rotor 14, main machine rotor 20, and PMG rotor 21 are mounted to the rotatable shaft 24 for rotation relative to the stators 16, 22, 23 which are rotationally fixed within the electrical machine assembly 210. The stators 16, 22, 23 may be mounted to any suitable part of a housing portion of the electrical machine assembly 210.

The rotatable shaft 24 further comprises at least a hollow portion for enclosing a rectifier assembly 27, further comprising a sleeve or shaft tube 30, which is contemplated to be non-conducting and further houses a rectifier subassembly 32. The shaft tube 30 is rotationally coupled for co-rotating with the rotatable shaft 24 and the rectifier subassembly 32, and electrically insulates the rectifier subassembly 32 from the rotatable shaft 24. It is envisioned that the shaft tube 30 may comprise any suitable non-conductive material.

The exciter rotor 14 is electrically connected to the rectifier subassembly 32 by way of conductors 36 (schematically shown as dotted lines). Additionally, the rectifier subassembly 32 is electrically connected to the main windings 38 of the main machine rotor 20 by way of conductors 36. The PMG stator 23 may also be electrically connected to the exciter stator 16 by way of conductors 36.

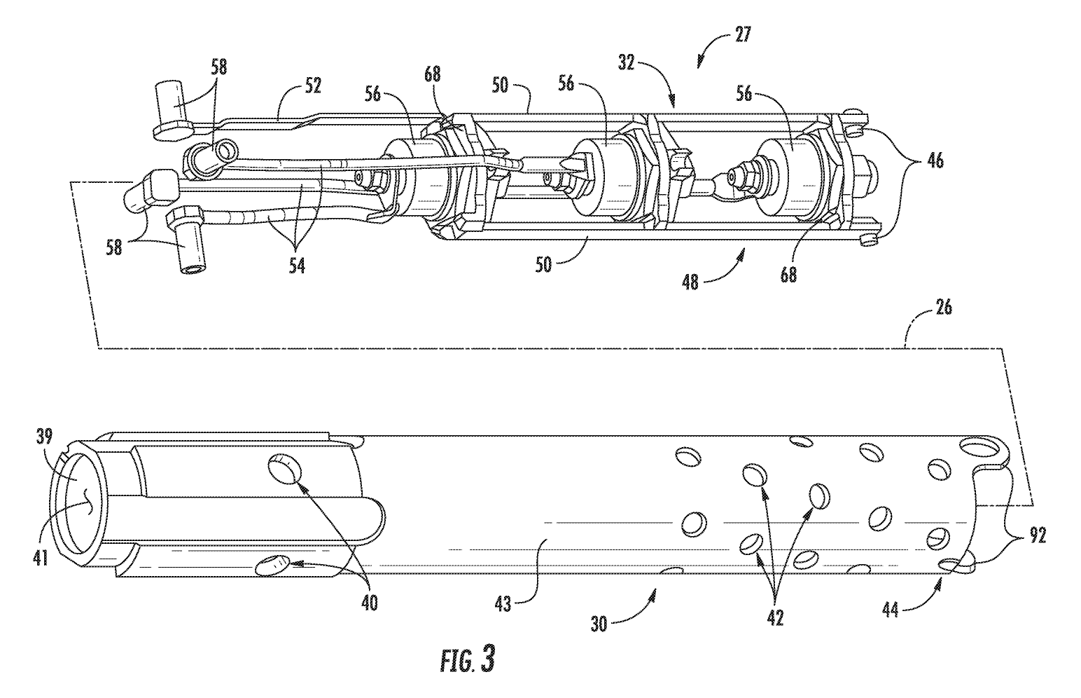

Turning now to FIG. 3, the details of the shaft tube 30 and the rectifier subassembly 32 will be described. The shaft tube 30 has a substantially cylindrical structure having an inner surface 39 defining an interior 41, an outer surface 43, opposing open ends, and may further include four mounting connector openings 40 spaced radially near an end of the shaft tube 30. The shaft tube 30 is also shown having optional access openings 42, some of which may be radially aligned for accessing portions of the rectifier subassembly 32. The shaft tube 30 is shown further comprising optional keyed recesses, or anchor fastener openings 44, and extension tabs 92, at the axial end of the shaft tube 30, opposite the mounting connector openings 40. The extension tabs 92 may provide proper axial spacing of the shaft tube 30 and/or rectifier assembly 27 within the rotatable shaft 24 and/or the electrical machine assembly 210, such that the shaft tube 30 cannot be axially over-inserted into the rotatable shaft 24. In one example, the extension tabs 92 may be radially keyed or indexed with the rotatable shaft 24 such that the shaft tube 30 may only be fully inserted when properly aligned with the rotatable shaft 24.

The rectifier subassembly 32 comprises an axially extending conductive frame, shown as a ladder structure 48, having at least two elongated side elements 50 electrically coupled to each other via at least one conductive diode seat 68. The rectifier subassembly 32 also includes a plurality of conductive bus bars 52, 54 shown radially spaced about the rectifier subassembly 32 axis, illustrated as a single resilient conductive DC bus bar 52 and three conductive, malleable output AC bus bars 54. As used herein, the term “resilient,” in describing the DC bus bar 52, denotes at least a portion of the bus bar 52 configured to bias the bus bar 52 outwardly to the straight position shown. Stated another way, the DC bus bar 52, when flexed, will bias back towards the non-flexed position shown. Similarly, the term “malleable” is used to describe the output AC bus bars 54 such that they may be easily altered, bent, or moveable as needed, and may be composed from non-resilient wiring, or other suitable conductive material.

The ladder structure 48 further comprises a set of axially spaced, forward-biased diodes 56 electrically coupling at least one of the AC bus bars 54 to the ladder structure 48. The ladder structure 48 is further electrically coupled to the DC bus bar 52. The ladder structure 48 may be made of any suitable conductive material, for example, aluminum.

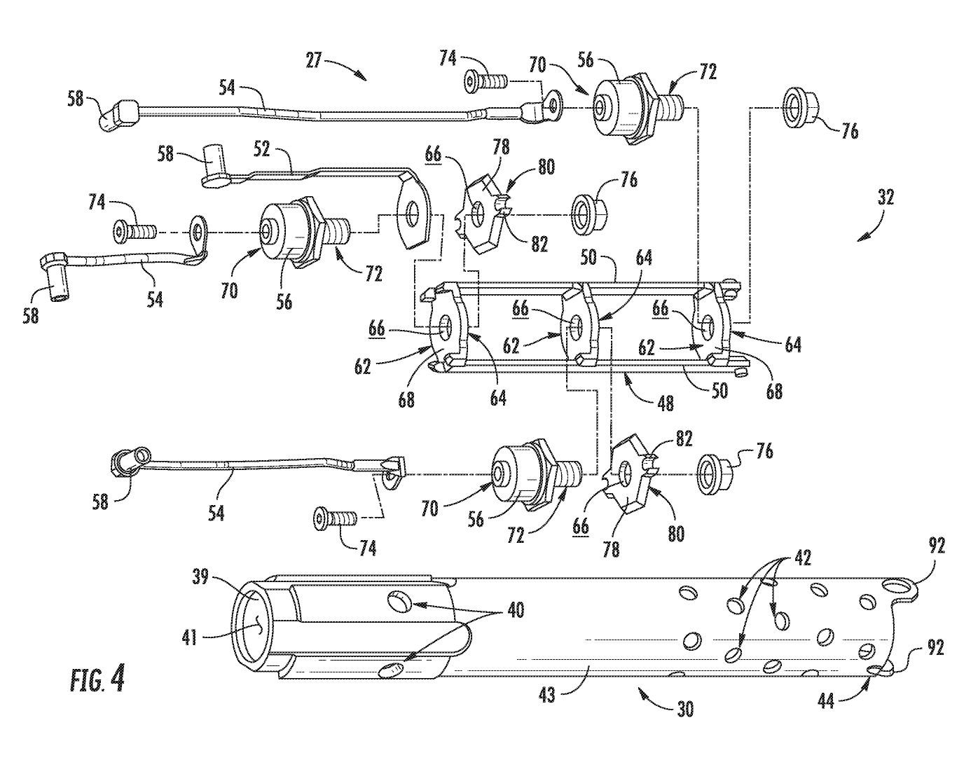

FIG. 4 illustrates an exploded perspective view of the rectifier subassembly. As illustrated, the ladder structure 48 further comprises axially spaced and axially facing conductive diode seats 68 electrically coupling the side elements 50, wherein each seat 68 further comprises axially opposing first and second segment faces 62, 64, and an opening 66 that may extend through the seat 68. In one example, the first segment face 62 of each seat 68 may operate and/or be configured for receiving the diode 56.

Each diode 56 may additionally comprise an anode terminal 70 and a cathode terminal 72, configured in the direction of the diode 56 bias, wherein each terminal 70, 72 may be coupled in a configurable way with any conductive surface coupling or suitable conductive mechanical or non-mechanical fasteners. In the illustrated example, the diodes 56 are shown having an anode terminal 70 configured to receive a mechanical fastener, such as a threaded screw 74, and a cathode terminal 72 configured to include a threaded screw receivable by a screw base 76.

The rectifier subassembly 32 may additionally comprise at least one non-conductive isolating segment 78 having at least one radially spaced guide channel, such as mounting connector 80, and configured to be placed adjacent to a second segment face 64 of a diode seat 68. In this sense, the isolating segment 78 may be supported by the diode seat 68, opposite the diode 56. The mounting connector 80 may further be defined by restraining elements, shown as semi-circular restraining arms 82, configured such that the AC bus bars 54 extending axially along the isolating segment 78 may be mounted by the receiving mounting connector 80. It is envisioned that the mounting connectors 80 may provide a suitable mounting coupling with the AC bus bars 54 wherein the mounting prevents damage to the bus bars 54, for instance, from vibrations or slight movements of the bus bars 54 relative to the mounting connector 80. In the example shown, the isolating segment 78 may further include an opening 66, similar in size, shape, and placement, to the opening 66 of a correspondingly adjacent diode seat 68.

When the rectifier subassembly 32 is assembled, each AC bus bar 54 may be electrically coupled with an anode terminal 70 of a diode 56 by, for example, a threaded screw 74. The diode 56 is further electrically coupled, via the cathode terminal 72, to a first segment face 62 of a diode seat 68. In the example illustrated, the threaded extension of the cathode terminal 72 may be received through the opening 66 of the diode seat 68, and further received through the opening 66 of the isolating segment 78, wherein the threaded extension of the cathode terminal 72 may be, for instance, compressively fixed by a screw base 76. As shown, the assembling of the AC bus bar 54 and diode 56 closest to the bus bar 52, 54 end of the ladder structure 48 may also include an electrical coupling of the cathode terminal 72 of the diode 56 to the DC bus bar 52 in addition to the electrical coupling of the terminal 72 to the ladder structure 48, for instance, by receiving the threaded extension of the terminal 72 through a corresponding opening 66 of the DC bus bar 52. In this instance, the ladder structure 48 and/or diode seat 68 may be keyed to mount the DC bus bar 52 in a certain configuration. Alternatively, the DC bus bar 52 may be electrically coupled to the ladder structure 48 at another mounting point. Alternative fixing methods and/or devices for assembling the above mentioned components are envisioned.

Additionally, when the rectifier subassembly 32 is assembled, the AC bus bars 54 extend axially along the rectifier subassembly 32 such that the diodes 56 may be electrically isolated from the ladder structure 48 and/or other diodes 56 by the mounting connectors 80 of the isolating segments 78. While substantially circular diodes 56, diode seats 68, and isolating segments 78 are illustrated, alternative shapes are envisioned. For example, circular or alternative shapes may include grooves or additional openings to allow for coolant and/or oil to transverse through the interior of, or about, the rectifier subassembly 32.

Additionally, as shown, the three AC bus bars 54 receive the respective three-phase AC output of the exciter rotor 14. Furthermore, the DC bus bar 52 is used for the transmission of the DC output to the second machine 18. Alternative arrangements and quantities of AC and DC bus bars 54, 52 are envisioned based on the needs and configuration of the electrical machine assembly 210.

Each bus bar 52, 54 comprises a first end having terminal connectors 58 for securing the respective DC and AC bus bars 52, 54 to the respective first and second machines 12, 18 by way of conductors 36. The AC bus bars 54 receive the input AC voltage from the first machine and the DC bus bars 52 deliver the output DC voltage from the rectifier subassembly 32. As illustrated, the terminal connectors 58 may be integrally formed and/or conjoined with the first end of the bus bars 54, 52. Alternatively, a fastener, such as a screw may be provided to aid in the mounting of the terminal connectors 58 to the first end of the bus bars 54, 52. Alternatively, non-mechanical fasteners, such as welding or adhesive may also be used. Additionally, while the AC bus bars 54 are described as flexible, it is envisioned that the DC and AC bus bars 52, 54 may comprise any combination of flexible and/or inflexible conductive materials.

The assembled components 48, 52, 54, 56 collectively define an axially extending, annular rectifier structure defining an axially extending interior. Alternative placement and configuration of the components 48, 52, 54, 56 are envisioned.

The ladder structure 48 may also optionally comprise assembly anchors, shown as protrusions 46, which may be keyed to interact with the corresponding anchor fastener openings 44 of the shaft tube 30. The protrusions 46 and anchor fastener openings 44 are configured such that when the rectifier subassembly 32 is inserted within the shaft tube 30, the protrusions 46 are radially keyed to be axially received within the fastener openings 44. Additionally, the terminal connectors 58 and mounting connector openings 40 are configured such that, when the shaft tube 30 and the rectifier subassembly 32 are assembled and keyed based on the corresponding protrusions 46 and fastener openings 44, the connectors 58 are received by the openings 40 to provide for electrical coupling between the AC connectors 58 and the first machine 12, and the DC connectors 58 and the second machine 18.

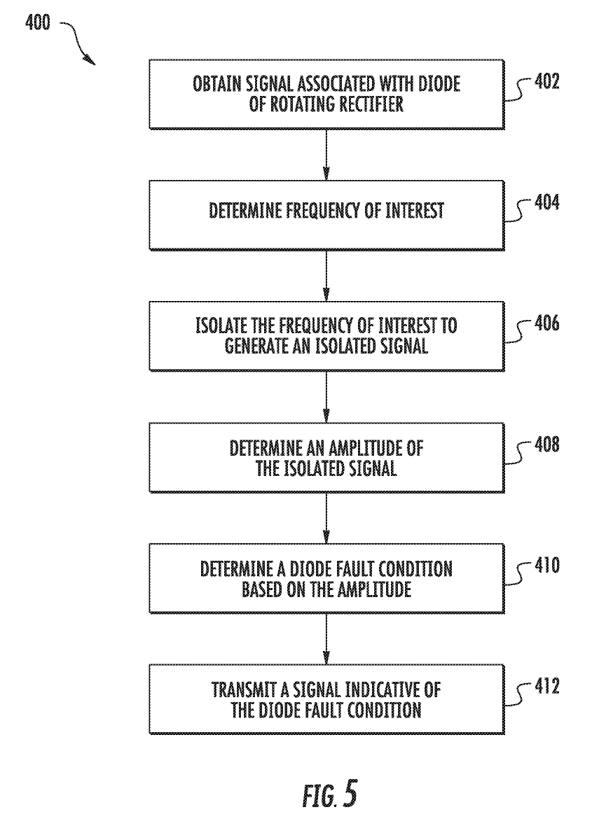

FIG. 5 depicts a flow diagram of an example method 400 for detecting a diode fault condition associated with a diode in a rotating rectifier according to example embodiments of the present disclosure. The method of FIG. 5 can be implemented using, for instance, the control system 500 of FIG. 6. FIG. 5 depicts steps performed in a particular order for purposes of illustration and discussion. Those of ordinary skill in the art, using the disclosures provided herein, will understand that various steps of any of the methods disclosed herein can be adapted, modified, rearranged, or modified in various ways without deviating from the scope of the present disclosure.

At (402), the method can include obtaining a signal associated with a diode in a rotating rectifier. The signal can be, for instance, a signal from an exciter field winding current sensor, a main armature voltage sensor, and/or a rectified DC bus voltage sensor associated with an electrical machine. Because of magnetic coupling, faults on the rotating electrical link between the exciter and main of an electrical machine can be evident on the armature of the main and the field of the exciter.

At (404), the method can include determining a frequency of interest. The frequency of interest can be determined based at least in part on shaft speed and the number of pole pairs of the exciter. For instance, in some embodiments, the frequency of interest can be determined as the product of the shaft speed and the number of pole pairs of the exciter.

At (406), the detected frequency of interest can be isolated from the signal to generate an isolated signal. Isolating the detected frequency of interest from the signal can include causing the signal to pass through a band-pass filter, wherein the band-pass filter targets the frequency of interest. Isolating the detected frequency of interest from the signal can include causing the signal to pass through a pseudo-Park transform, wherein a reference frequency of the pseudo-Park transform is equal to the frequency of interest. Isolating the detected frequency of interest from the signal can include causing the signal to pass through a phase-locked loop, wherein the phase-locked loop is locked to the frequency of interest. Isolating the detected frequency of interest from the signal can include causing the signal to pass through a Fourier-series integration, wherein the Fourier-series integration is set at the frequency of interest. At (408), an amplitude of the isolated signal can be determined.

At (410), a diode fault condition can be determined based on the determined amplitude. Determining a diode fault condition based on the determined amplitude can include determining that the diode fault condition is a shorted diode when the amplitude of the isolated signal exceeds a first threshold. Determining a diode fault condition can include determining that the diode fault condition is an open diode when the amplitude of the isolated signal remains above a second threshold without exceeding the first threshold for a period of time. The second threshold can be less than the first threshold. The designation of “first” and “second” to the thresholds does not indicate an order in which the thresholds were exceeded. As detailed above, the second threshold can be exceeded before the first threshold is exceeded.

At (412), a signal indicative of the determined diode fault condition can be transmitted. The signal indicative of the determined diode fault can be transmitted to an output device for a pilot and/or passenger. The signal indicative of the determined diode fault can be transmitted to a ground system. The signal can also be transmitted to a control system for the control system to take a control action based on the signal. The control action can be associated with replacing the diode. Alternatively or additionally, the control action can be associated with updating a database to indicate that the diode is defective.

FIG. 6 depicts a block diagram of an example computing system that can be used to implement the control system 500 or other systems according to example embodiments of the present disclosure. As shown, the control system 500 can include one or more computing device(s) 502. The one or more computing device(s) 502 can include one or more processor(s) 504 and one or more memory device(s) 506. The one or more processor(s) 504 can include any suitable processing device, such as a microprocessor, microcontroller, integrated circuit, logic device, or other suitable processing device. The one or more memory device(s) 506 can include one or more computer-readable media, including, but not limited to, non-transitory computer-readable media, RAM, ROM, hard drives, flash drives, or other memory devices.

The one or more memory device(s) 506 can store information accessible by the one or more processor(s) 504, including computer-readable instructions 508 that can be executed by the one or more processor(s) 504. The instructions 508 can be any set of instructions that when executed by the one or more processor(s) 504, cause the one or more processor(s) 504 to perform operations. The instructions 508 can be software written in any suitable programming language or can be implemented in hardware. In some embodiments, the instructions 508 can be executed by the one or more processor(s) 504 to cause the one or more processor(s) 504 to perform operations, such as the operations for detecting a diode fault, as described with reference to FIG. 4.

The memory device(s) 506 can further store data 510 that can be accessed by the processors 504. For example, the data 510 can include signals, frequencies, component data, component speed data, etc. as described herein. The data 510 can include one or more table(s), function(s), algorithm(s), model(s), equation(s), etc. for detecting a diode fault according to example embodiments of the present disclosure.

The one or more computing device(s) 502 can also include a communication interface 512 used to communicate, for example, with the other components of the system and/or other computing devices. The communication interface 512 can include any suitable components for interfacing with one or more network(s), including for example, transmitters, receivers, ports, controllers, antennas, or other suitable components.

The control system 500 can receive one or more signals from sensors, such as an exciter field winding current sensor 514 and a main armature voltage sensor 516. The signals can be processed according to example aspects of the present disclosure to determine a diode fault condition associated with a diode in a rotating rectifier according to example aspects of the present disclosure.

The technology discussed herein makes reference to computer-based systems and actions taken by and information sent to and from computer-based systems. One of ordinary skill in the art will recognize that the inherent flexibility of computer-based systems allows for a great variety of possible configurations, combinations, and divisions of tasks and functionality between and among components. For instance, processes discussed herein can be implemented using a single computing device or multiple computing devices working in combination. Databases, memory, instructions, and applications can be implemented on a single system or distributed across multiple systems. Distributed components can operate sequentially or in parallel.

Although specific features of various embodiments may be shown in some drawings and not in others, this is for convenience only. In accordance with the principles of the present disclosure, any feature of a drawing may be referenced and/or claimed in combination with any feature of any other drawing.

This written description uses examples to disclose the present disclosure, including the best mode, and also to enable any person skilled in the art to practice the present disclosure, including making and using any devices or systems and performing any incorporated methods. The patentable scope of the present disclosure is defined by the claims and can include other examples that occur to those skilled in the art. Such other examples are intended to be within the scope of the claims if they include structural elements that do not differ from the literal language of the claims, or if they include equivalent structural elements with insubstantial differences from the literal language of the claims.

What is claimed is:

1. A method for determining a diode fault condition in a rotating rectifier associated with an electrical machine in an aircraft comprising:
obtaining, by one or more processors, a signal associated with a diode of a rotating rectifier;
determining, by the one or more processors, a frequency of interest;
isolating, by the one or more processors, the frequency of interest from the signal to generate an isolated signal;
determining, by the one or more processors, an amplitude of the isolated frequency of interest; and
determining, by the one or more processors, a diode fault condition based on the determined amplitude.

2. The method of claim 1, wherein the method further comprises transmitting, by the one or more processors, a signal indicative of the diode fault condition.

3. The method of claim 2, wherein in response to determining the diode fault condition, the one or more processors are further configured to generate a control action associated with replacing the diode.

4. The method of claim 1, wherein the signal is associated with an exciter field winding current sensor.

5. The method of claim 1, wherein the frequency of interest is determined based at least in part on a shaft speed and a number of pole pairs associated with an exciter of the electrical machine.

6. The method of claim 1, wherein isolating, by the one or more processors, the frequency of interest from the signal comprises causing the signal to pass through a pseudo-Park transform, wherein a reference frequency of the pseudo-Park transform is equal to the frequency of interest.

7. The method of claim 1, wherein isolating, by the one or more processors, the frequency of interest from the signal comprises causing the signal to pass through a phase-locked loop, wherein the phase-locked loop is locked to the frequency of interest.

8. The method of claim 1, wherein isolating, by the one or more processors, the frequency of interest from the signal further comprises causing the signal to pass through a Fourier-series integration, wherein the Fourier-series integration is set at the frequency of interest.

9. The method of claim 4, wherein isolating, by the one or more processors, the detected frequency of interest from the signal further comprises causing the signal to pass through a band-pass filter, wherein the band-pass filter targets the frequency of interest.

10. The method of claim 1, wherein the diode fault condition is determined to be a shorted diode when the amplitude of the isolated signal exceeds a first threshold.

11. The method of claim 10, wherein the diode fault condition is determined to be an open diode when the amplitude of the isolated signal remains above a second threshold without exceeding the first threshold for a period of time, the second threshold being less than the first threshold.

12. A system for determining a diode fault condition in a rotating rectifier associated with an electrical machine in an aircraft comprising:
one or more memory devices; and
one or more processors configured to:
obtain a signal associated with a diode of a rotating rectifier;
determine a frequency of interest;
isolate the frequency of interest from the signal to generate an isolated signal;
determine an amplitude of the isolated frequency of interest; and
determine a diode fault condition based on the determined amplitude.

13. The system of claim 12, wherein the one or more processors are further configured to transmit a signal indicative of the determined diode fault.

14. The system of claim 12, wherein in response to determining the diode fault condition, the one or more processors are further configured to generate a control action associated with replacing the diode.

15. The system of claim 12, wherein the signal is associated with a main armature voltage sensor.

16. The system of claim 12, wherein the frequency of interest is determined based at least in part on a shaft speed and a number of pole pairs associated with an exciter of the electrical machine.

17. The system of claim 12, wherein the one or more processors are further configured to cause the signal to pass through a pseudo-Park transform, wherein a reference frequency of the pseudo-Park transform is equal to the frequency of interest.

18. The system of claim 12, wherein the one or more processors are further configured to cause the signal to pass through a phase-locked loop, wherein the phase-locked loop is locked to the frequency of interest.

19. The system of claim 12, wherein the one or more processors are further configured to cause the signal to pass through a Fourier-series integration, wherein the Fourier-series integration is set at the frequency of interest.

20. The system of claim 12, wherein the one or more processors are further configured to cause the signal to pass through a band-pass filter, wherein the band-pass filter targets the frequency of interest.
